(19) United States
(12) Patent Application Publication
(10) Pub. No.: US 2026/0015251 A1
(43) Pub. Date: Jan. 15, 2026

(54) OXIDE FERROELECTRIC MATERIALS

(71) Applicant: SAMSUNG ELECTRONICS CO., LTD., Suwon-si (KR)

(72) Inventors: Nikhil SIVADAS, Boston, MA (US); Yongwoo Shin, Concord, MA (US)

(73) Assignee: SAMSUNG ELECTRONICS CO., LTD., Suwon-si (KR)

(21) Appl. No.: 18/933,796

(22) Filed: Oct. 31, 2024

Related U.S. Application Data
(60) Provisional application No. 63/669,528, filed on Jul. 10, 2024.

(51) Int. Cl. C01G 21/08; C01G 33/00; C01G 39/02; C01G 41/02; H01L 29/51; H10N 70/00

(52) U.S. Cl. CPC C01G 21/08; C01G 33/00; C01G 39/02; C01G 41/02; C01P 2002/50; C01P 2002/76; C01P 2002/77; C01P 2006/40; H10D 1/682; H10D 64/689; H10N 70/8836

(57) ABSTRACT

A meta-stable ferroelectric structure including one of the following oxides: an isovalent combination of the formula MₓM′₁₋ₓO_{2-δ}, wherein M, M′={Zr, Hf, Pb, W, Mo, Nb, Te, Ti}, 0≤x≤1, 0≤δ≤0.5 excluding {HfₓZr₁₋ₓO₂ all x in Pca2₁ phase}; an aliovalent combination of the formula MIₓMII₁₋ₓO_{2-δ}, wherein MI, MII={Bi, Y, Ta, In, Mo, Nb, Sc, Tl, Pd, Sb, W, Cr, Ge, Rh, Ti, Ag, Sn, Au, Ir, Pd, Ni, Ru, Hg}, 0≤x≤1, 0≤δ≤0.5, excluding certain aliovalent combinations; or an isovalent-aliovalent combination of the formula MₓMI_{y}MII_{1-x-y}O_{2-δ}, wherein M, MI, and MII are as set forth above, 0≤x≤1, 0≤y≤1, 0≤δ≤0.5; wherein the ferroelectric structure is in a Pca2₁ or Pmn2₁ space group or a subgroup thereof.

### CROSS-REFERENCE TO RELATED APPLICATION

This application is based on and claims priority from U.S. Provisional Application No. 63/669,528 filed on Jul. 10, 2024 in the U.S. Patent and Trademark Office, the disclosure of which is incorporated herein by reference in its entirety.

### BACKGROUND

### 1. Field

Embodiments relate to a meta-stable ferroelectric structure comprising an oxide of one of the following chemistries: an isovalent combination of the formula MₓM′₁₋ₓO_{2-δ}, wherein M, M′={Zr, Hf, Pb, W, Mo, Nb, Te, Ti}, 0≤x≤1, 0≤δ≤0.5 excluding {HfₓZr₁₋ₓO₂ all x in Pca2₁ phase}; an aliovalent combination of the formula MIₓMII₁₋ₓO_{2-δ}, wherein MI, MII={Bi, Y, Ta, In, Mo, Nb, Sc, Tl, Pd, Sb, W, Cr, Ge, Rh, Ti, Ag, Sn, Au, Ir, Pd, Ni, Ru, Hg}, 0≤x≤1, 0≤ δ≤0.5, excluding aliovalent combinations in which MI is Ta, Nb or W where MII is Y or Sc or in which MI is Y or Sc where MII is Ta, Nb or W; or an isovalent-aliovalent combination of the formula MₓMI_{y}MII_{1-x-y}O_{2-δ}, wherein M, MI, and MII are as set forth above, 0≤x≤1, 0≤y≤1, 0≤δ≤0.5; wherein the ferroelectric structure is in a Pca2₁ or Pmn2₁ space group or a subgroup thereof.

### 2. Description of the Related Art

Ferroelectricity (FE) in HfO₂ was first observed in 2011, many years after its commercial use as a gate-dielectric material. This FE is unique in the sense that it is persistent in thin-films. Later, ZrO₂ was also found to form FE in this phase.

Ferroelectric HfO₂ is illustrated in FIG. 1. In this regard, FIG. 1 shows two distinct states (polarization up and polarization down). An electric field is used to switch the states.

Typical applications of ferroelectric materials include the following:
Non-volatile memory devices-Polarization stays (“1”) when the field is removed. The polarization can be switched on application of a different field (“0”). Applications for FE-RAMs are currently being explored.
Tunnel junctions: FTJs are explored in diode-like applications. FEFETs are also being explored.
Capacitors-Some FE materials exhibit a high dielectric constant. This is useful for better capacitors.
Sensors-Sensitivity to E-field allows FE materials to be used as RF and IR sensors. They are also used in ultrasound applications, as optical components, and as tunable microwave components (high coercive field allows microwave tunability at <3V).
Other applications include piezoelectrics, detectors for vibration, pyroelectricity, etc.

HfO₂ is often used for the following reasons:
CMOS compatible: HfO₂ has been used as a high-k gate dielectric for over 2 decades.
Typical FE materials lose their FE property in thin film, but HfO₂ retains its FE property in thin film (even down to 1 nm).

However, challenges with existing HfO₂ technology include the following:
The FE phase of HfO₂ (Pca2₁) is not the lowest energy phase of HfO₂ (Ehull˜28 meV/atom). This is typically stabilized by using an appropriate substrate (SiO₂) or by doping (Si, Al, Y, etc.).
There are over 5 identified phases of HfO₂ and other proposed polar phases (Pmn2₁). Naturally, there are more competing phases to consider within the same 1:2 stoichiometry.

In view of the above, there is a need to identify other metal oxides that are stable in the polar phases (Pca2₁, Pmn2₁) with low Ehull and fewer competing phases, which can lead to them being used alternatively as FE materials.

Information disclosed in this Background section has already been known to the inventors before achieving the disclosure of the present application or is technical information acquired in the process of achieving the disclosure. Therefore, it may contain information that does not form the prior art that is already known to the public.

### SUMMARY

To satisfy the above need, the present disclosure identifies other oxides that are meta-stable in the same phase of FE-HfO₂. This will significantly expand the candidates for thin film FE applications (e.g., capacitors, sensors, field effect transistors).

In particular, the present disclosure identifies a new list of meta-stable ferroelectric oxides and identifies isovalent and aliovalent combinations that are meta-stable in the FE-HfO₂ phase. The present disclosure also provides a strategy using an appropriate substrate to experimentally synthesize these phases.

Thus, the present disclosure expands the list of possible oxide FE materials from just two chemistries (Hf, Zr) to many others. The present disclosure also provides a strategy to experimentally grow them (by using appropriate substrates).

Advantages of embodiments of the present disclosure include that the list of chemistries provided by the present disclosure gives considerable flexibility in making thin film FE materials. By changing the chemistries and ratios, it might be possible to control existing properties or even engineer new functionalities. The present disclosure also provides a list of suitable substrates to grow these new oxide FE materials

A first embodiment of the present disclosure provides a meta-stable ferroelectric structure comprising one of the following oxides:
an isovalent combination of the formula MₓM′₁₋ₓO_{2-δ}, wherein M and M′ are independently selected from the group consisting of Zr, Hf, Pb, W, Mo, Nb, Te, and Ti, wherein 0≤x≤1 and 0≤δ≤0.5, excluding HfₓZr₁₋ₓO₂ for all x in Pca2₁ phase;
an aliovalent combination of the formula MIₓMII₁₋ₓO_{2-δ}, wherein MI and MII are independently selected from the group consisting of Bi, Y, Ta, In, Mo, Nb, Sc, Tl, Pd, Sb, W, Cr, Ge, Rh, Ti, Ag, Sn, Au, Ir, Ni, Ru, and Hg, wherein 0≤x≤1 and 0≤δ≤0.5, excluding aliovalent combinations in which MI is Ta, Nb or W where MII is Y or Sc or in which MI is Y or Sc where MII is Ta, Nb or W; or
an isovalent-aliovalent combination of the formula MₓMI_{y}MII_{1-x-y}O_{2-δ}, wherein M, MI, and MII are as set forth above and 0≤x≤1, 0≤y≤1, and 0≤δ≤0.5;
wherein the ferroelectric structure is in a Pca2₁ or Pmn2₁ space group or a subgroup thereof.

A second embodiment of the present disclosure provides a meta-stable ferroelectric structure of the first embodiment, wherein the oxide is the isovalent combination.

A third embodiment of the present disclosure provides a meta-stable ferroelectric structure of the first embodiment, wherein the oxide is the aliovalent combination.

A fourth embodiment of the present disclosure provides a meta-stable ferroelectric structure of the first embodiment, wherein the oxide is the isovalent-aliovalent combination.

A fifth embodiment of the present disclosure provides a meta-stable ferroelectric structure of the second embodiment, wherein the oxide is selected from the group consisting of PbO₂, WO₂, NbO₂, and MoO₂, and wherein the ferroelectric structure is in the Pca2₁ space group or a subgroup thereof.

A sixth embodiment of the present disclosure provides a meta-stable ferroelectric structure of the second embodiment, wherein the oxide is selected from the group consisting of NbO₂, TeO₂, TiO₂, and PbO₂, and wherein the ferroelectric structure is in the Pmn2₁ space group or a subgroup thereof.

A seventh embodiment of the present disclosure provides a meta-stable ferroelectric structure of the third embodiment, wherein the oxide is the aliovalent combination of the formula MIₓMI₁₋ₓO₂, wherein MI and MII are independently selected from the group consisting of Bi, In, Ag, Rh, Y, Mo, Ti, W, Ni, Au, Sn, Sc, Sb, Tl, Cr, Ru, Hg, Pd, Ge, Ir, Ta, and Nb, excluding aliovalent combinations in which MI is Ta, Nb or W where MII is Y or Sc or in which MI is Y or Sc where MII is Ta, Nb or W, and wherein the ferroelectric structure is in the Pca2₁ space group or a subgroup thereof.

A eighth embodiment of the present disclosure provides a meta-stable ferroelectric structure of the seventh embodiment, wherein MI and MII are selected from one of the following MI and MII combinations: Ta—Mo, Nb—In, Bi—Nb, Bi—In, Bi—Sc, Nb—Mo, Bi—Pd, Ta—In, Bi—Ta, Bi—Y, and Nb—Tl.

A ninth embodiment of the present disclosure provides a meta-stable ferroelectric structure of the third embodiment, wherein the oxide is aliovalent combination of the formula MIₓMII₁₋ₓO₂, wherein MI and MII are independently selected from the group consisting of Bi, Nb, In, Rh, Ti, Y, Ta, W, Cr, Sc, Tl, Au, Ir, Mo, and Ge, and wherein the ferroelectric structure is in the Pmn2₁ space group or a subgroup thereof.

A tenth embodiment of the present disclosure provides a vertical channel transistor comprising a meta-stable ferroelectric structure of the first embodiment.

An eleventh embodiment of the present disclosure provides a FE-RAM comprising a meta-stable ferroelectric structure of the first embodiment.

A twelfth embodiment of the present disclosure provides a FTJ comprising a meta-stable ferroelectric structure of the first embodiment.

A thirteenth embodiment of the present disclosure provides a FE-FET comprising a meta-stable ferroelectric structure of the first embodiment.

A fourteenth embodiment of the present disclosure provides a capacitor comprising a meta-stable ferroelectric structure of the first embodiment.

A fifteenth embodiment of the present disclosure provides a sensor comprising a meta-stable ferroelectric structure of the first embodiment.

A sixteenth embodiment of the present disclosure provides a switch comprising a meta-stable ferroelectric structure of the first embodiment.

A seventeenth embodiment of the present disclosure provides a meta-stable ferroelectric structure comprising one of the following oxides:
an isovalent combination of the formula MₓM′₁₋ₓO_{2-δ}, wherein M and M′ are independently selected from the group consisting of Zr, Hf, Pb, Mo, Nb, Te, and Ti, wherein 0≤x≤1 and 0≤δ≤0.5, excluding HfₓZr₁₋ₓO₂ for all x in Pca2₁ phase;
an aliovalent combination of the formula MIₓMII₁₋ₓO_{2-δ}, wherein MI and MII are independently selected from the group consisting of Bi, In, Mo, Tl, Pd, Sb, Cr, Ge, Rh, Ti, Ag, Sn, Au, Ir, Ni, Ru, and Hg, wherein 0≤x≤1 and 0≤δ≤0.5; or
an isovalent-aliovalent combination of the formula MₓMI_{y}MII_{1-x-y}O_{2-δ}, wherein M, MI, and MII are as set forth above and 0≤x≤1, 0≤y≤1, and 0≤δ≤0.5;
wherein the ferroelectric structure is in a Pca2₁ or Pmn2₁ space group or a subgroup thereof.

A eighteenth embodiment of the present disclosure provides a meta-stable ferroelectric structure of the seventeenth embodiment, wherein the oxide is the aliovalent combination.

A nineteenth embodiment of the present disclosure provides a meta-stable ferroelectric structure of the first embodiment, comprising one of the following oxides:
an isovalent combination of the formula MₓM′₁₋ₓO₂, wherein M and M′ are independently selected from the group consisting of Zr, Hf, Pb, W, Mo, Nb, and Te, wherein 0≤x≤1, excluding HfₓZr₁₋ₓO₂ for all x;
an aliovalent combination of the formula MIₓMII₁₋ₓO₂, wherein MI and MII are independently selected from the group consisting of Bi, Y, Ta, In, Nb, Sc, Tl, Rh, Ti, Au, and Ir, wherein 0≤x≤1, excluding aliovalent combinations in which MI is Ta or Nb where MII is Y or Sc or in which MI is Y or Sc where MII is Ta or Nb; or
an isovalent-aliovalent combination of the formula MₓMI_{y}MII_{1-x-y}O₂, wherein M, MI, and MII are as set forth above and 0≤x≤1 and 0≤y≤1;
wherein the ferroelectric structure is in a Pca2₁ or Pmn2₁ space group or a subgroup thereof.

A twentieth embodiment of the present disclosure provides a meta-stable ferroelectric structure of the seventeenth embodiment, comprising one of the following oxides:
an isovalent combination of the formula MₓM′₁₋ₓO₂, wherein M and M′ are independently selected from the group consisting of Zr, Hf, Pb, Mo, Nb, and Te, wherein 0≤x≤1, excluding HfₓZr₁₋ₓO₂ for all x;
an aliovalent combination of the formula MIₓMII₁₋ₓO₂, wherein MI and MII are independently selected from the group consisting of Bi, In, Tl, Rh, Ti, Au, and Ir, wherein 0≤x≤1; or
an isovalent-aliovalent combination of the formula MₓMI_{y}MII_{1-x-y}O₂, wherein M, MI, and MII are as set forth above and 0≤x≤1 and 0≤y≤1;
wherein the ferroelectric structure is in a Pca2₁ or Pmn2₁ space group or a subgroup thereof.

### BRIEF DESCRIPTION OF DRAWINGS

The patent or application file contains at least one drawing executed in color. Copies of this patent or patent application publication with color drawing(s) will be provided by the Office upon request and payment of the necessary fee.

Example embodiments of the present disclosure will be more clearly understood from the following detailed description taken in conjunction with the accompanying drawing in which:

FIG. 1 shows ferroelectric HfO₂ in its two distinct states.

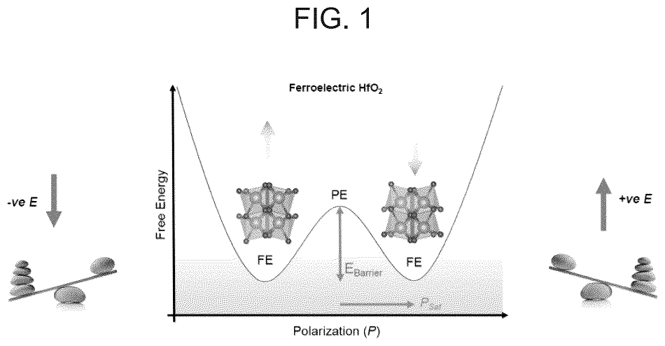

FIG. 2 shows the FE-HfO₂ structure with space group Pca2₁.

FIG. 3 shows the NEB barrier computed for HfO₂ and its comparison with previous reporting.

FIG. 4 shows NEB on an isovalent candidate, using Mo as an example.

FIG. 5 shows structures of the present disclosure for FE candidates from aliovalent 100% Hf substitution.

FIG. 6 shows an embodiment of the present disclosure based on an aliovalent combination.

FIG. 7 shows aliovalent combinations of the present disclosure (Ehull<50 meV/atom).

FIG. 8 shows aliovalent combinations of the present disclosure (50 meV/atom<Ehull<100 meV/atom).

FIG. 9 shows aliovalent combinations of the present disclosure (100 meV/atom<Ehull<150 meV/atom).

### DETAILED DESCRIPTION OF EXAMPLE EMBODIMENTS

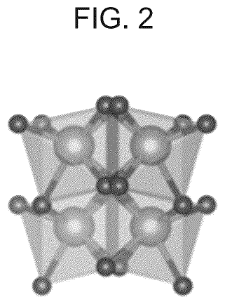

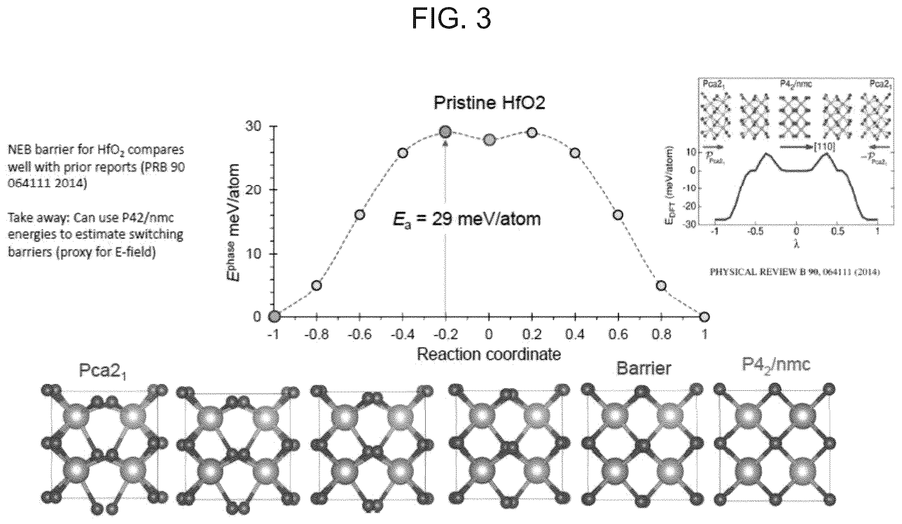

FIG. 2 shows the FE-HfO₂ structure with space group Pca2₁. A second phase with Pmn2₁ is theorized to also be FE. FIG. 3 shows that the NEB barrier computed for HfO₂ compares well with previous reporting, so P4₂/nmc energies can be used to estimate switching barriers (a proxy for E-field).

Based on a systematic study of all possible isovalent oxides and aliovalent oxides that are meta-stable in the FE phases of HfO₂, the present disclosure provides meta-stable ferroelectric structures including oxides of the following chemistries:
an isovalent combination of the formula MₓM′₁₋ₓO_{2-δ}, wherein M and M′ are independently selected from the group consisting of Zr, Hf, Pb, W, Mo, Nb, Te, and Ti, wherein 0≤x≤1 and 0≤δ≤0.5, excluding HfₓZr₁₋ₓO₂ for all x in Pca2₁ phase;
an aliovalent combination of the formula MIₓMII₁₋ₓO_{2-δ}, wherein MI and MII are independently selected from the group consisting of Bi, Y, Ta, In, Mo, Nb, Sc, Tl, Pd, Sb, W, Cr, Ge, Rh, Ti, Ag, Sn, Au, Ir, Ni, Ru, and Hg, wherein 0≤x≤1 and 0≤δ≤0.5, excluding aliovalent combinations in which MI is Ta, Nb or W where MII is Y or Sc or in which MI is Y or Sc where MII is Ta, Nb or W; or
an isovalent-aliovalent combination of the formula MₓMI_{y}MII_{1-x-y}O_{2-δ}, wherein M, MI, and MII are as set forth above and 0≤x≤1, 0≤y≤1, and 0≤δ≤0.5;
wherein the ferroelectric structure is in a Pca2₁ or Pmn2₁ space group or a subgroup thereof for applications including FE-RAM, vertical channel transistors, FE-FET, FTJ, capacitors, sensors and switches.

The identified oxides are nonmetallic with relatively low Ehull making them experimentally synthesizable under appropriate conditions (including choosing the right substrate). The appropriate substrate choice to stabilize these FE materials is also listed. Thus, the ferroelectrics can be grown on an appropriate substrate of choice (e.g., SiO₂) using typical growth methods like thermal oxidation, atomic layer deposition, pulsed laser deposition, chemical vapor deposition, plasma oxidation, wet anodization or other chemical treatments. For example, atomic layer deposition growth of HfO₂ can be done using CpHf(NMe₂)₃ and (CpMe)Hf(NMez)₃ (Cp, cyclopentadienyl=C₅H₅) as precursors using O₃ as the oxygen source between 250° C. and 400° C. (see Niinistö et al., “Growth and phase stabilization of HfO₂ thin films by ALD using novel precursors,” Journal of Crystal Growth, Vol. 312, Issue 2, Jan. 1, 2010, pp. 245-249), and embodiments of the present disclosure can be made in a similar manner using precursors appropriate for making those embodiments.

Thus, FE candidates from isovalent 100% Hf substitution include the following candidates shown in Table 1 below:

TABLE 1

| | | | Meta phase | band | | | | | |
|---|---|---|---|---|---|---|---|---|---|
| | | e_hull | P4_2/nmc | gap | | lattice | | | |
| | Composition | (eV) | (eV) | (eV) | spacegroup | a (Å) | b (Å) | c (Å) | Substrate |
| Spacegroup: | Ref. HfO2 | 0.028 | 0.056 | [symbol] | Pca2_1 | 5.046 | 5.078 | 5.27 | Si_T/O/M |
| Pca2_1 | Ref. ZrO2 | 0.022 | 0.037 | [symbol] | Pca2_1 | 5.123 | 5.154 | 5.342 | Hf_M/ [symbol] |
| | PbO2 | 0.002 | 0.042 | 0.15 | Pca2_1 | 5.131 | 5.580 | [symbol] | Hf_M |
| | WO2 | [symbol] | 0 | 2.758 | Pca2_1 | 5.088 | 5.091 | 5.196 | Si_H/M/O |
| | MoO2 | [symbol] | 0 | 1.500 | Pca2_1 | 5.051 | 5.051 | 5.181 | Si_T/Si_O |
| | NbO2 | 0.106 | 0.184 | 0.508 | Pca2_1 | 5.017 | 5.050 | 5.215 | Si_T |
| Spacegroup: | Ref. HfO2 | 0.049 | 0.056 | [symbol] | Pmn2_1 | 3.407 | 5.149 | 3.845 | [symbol] /LTO-ac |
| Pmn2_1 | Ref. ZrO2 | [symbol] | 0.037 | 3.188 | Pmn2_1 | 3.479 | 5.244 | [symbol] | LTO-ac |
| | NbO2 | 0.045 | [symbol] | 0.077 | Pmn2_1 | 3.168 | 5.094 | 3.994 | [symbol] |
| | PbO2 | 0.066 | 0.055 | 0.023 | Pmn2_1 | 3.630 | 5.551 | 4.019 | [symbol] /NSO-ac |
| | TeO2 | 0.122 | [symbol] | 1.627 | Pmn2_1 | 3.367 | [symbol] | [symbol] | |
| | TiO2 | 0.140 | 0.144 | 1.795 | Pmn2_1 | 3.163 | [symbol] | 3.679 | AO-ac/LuAO-ac |

[symbol]

indicates data missing or illegible when filed

In Table 1, the meta phase value is indicative of a barrier to polarization switching.

Additionally, in Table 1, the substrate is a substrate stabilizing the meta-stable phase.

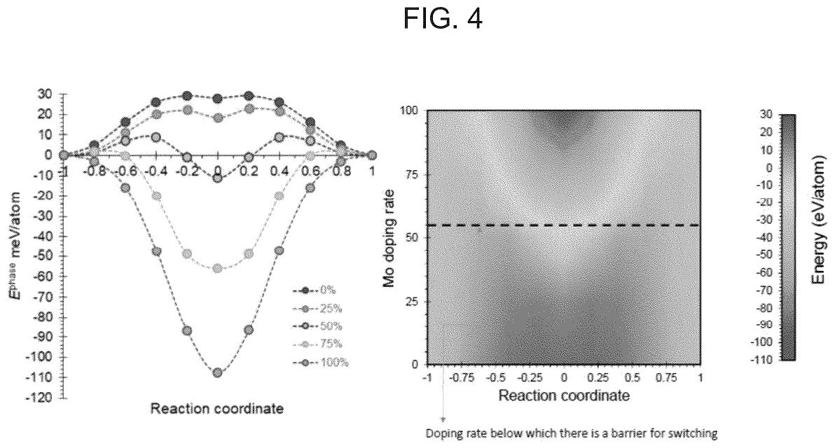

FIG. 4 shows NEB on an isovalent candidate, using Mo as an example.

With respect to the aliovalent embodiments, FE candidates from aliovalent 100% Hf substitution include the following candidates:
Space group: Pca2₁
   Ehull<150 meV/atom with finite band gap
   MIₓMII₁₋ₓO₂ (MI, MII={Bi, Nb, In, Ag, Rh, Y, Ta, Ti, W, Ni, Au, Sn, Sc, Sb, Tl, Cr, Mo, Ru, Hg, Pd, Ge, Ir})
   Examples of MI and MII combinations (under 30 meV/atom): Ta—Mo, Nb—In, Bi—Nb, Bi—In, Nb—Y, Ta—Y, Bi—Sc, Nb—Mo, Bi—Pd, Ta—In, Bi—Ta, Bi—Y, Nb—Tl, etc. Particular embodiments of the present disclosure include Ta—Mo, Nb—In, Bi—Nb, Bi—In, Bi—Sc, Nb—Mo, Bi—Pd, Ta—In, Bi—Ta, Bi—Y, and Nb—Tl.
Space group: Pmn2₁
   Ehull<150 meV/atom with finite band gap
   MIₓMII₁₋ₓO₂ (MI, MII={Bi, Nb, In, Rh, Ti, Y, Ta, W, Cr, Sc, Tl, Au, Ir, Mo, Ge})

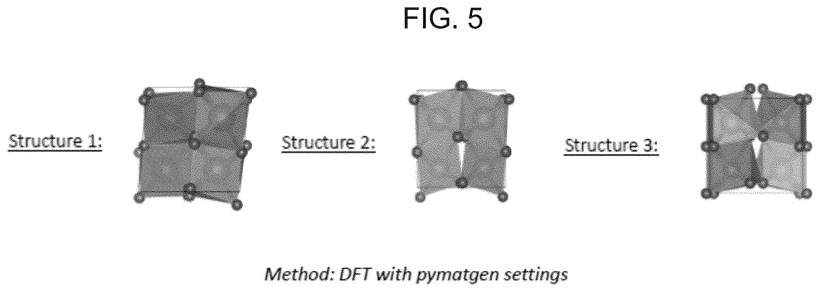

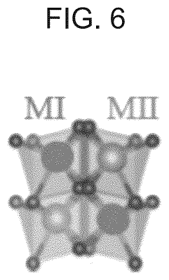

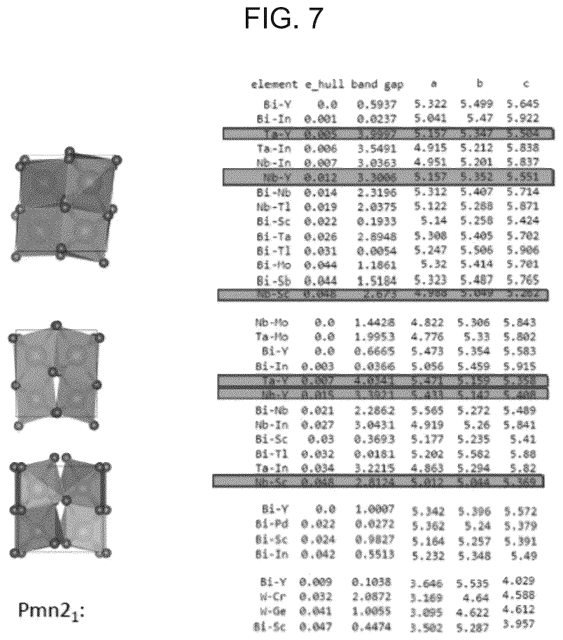

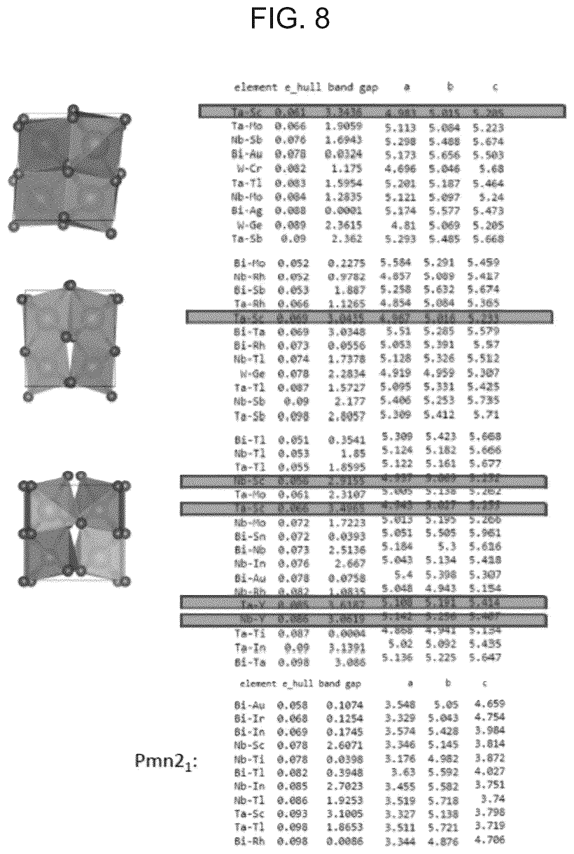

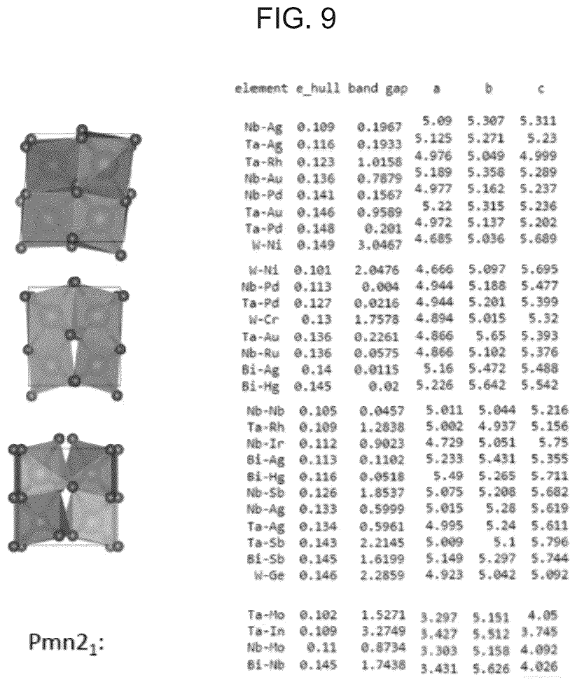

Structures of the present disclosure for FE candidates from aliovalent 100% Hf substitution are shown in FIG. 5, and an embodiment of the present disclosure based on an aliovalent combination is shown in FIG. 6. FIG. 7 shows aliovalent combinations of the present disclosure with Ehull<50 meV/atom, FIG. 8 shows aliovalent combinations of the present disclosure with 50 meV/atom<Ehull<100 meV/atom, and FIG. 9 shows aliovalent combinations of the present disclosure with 100 meV/atom<Ehull<150 meV/atom).

A list of substrates which can be used in connection with the present disclosure is shown in Table 2 below.

TABLE 2
Substrate list

| index | mp-id | Composition | [symbol] | Spacegroup | a | b | c | band gap |
|---|---|---|---|---|---|---|---|---|
| [symbol] | [symbol] | SiO2 | Tetragonal | [symbol] | [symbol] | [symbol] | [symbol] | [symbol] |
| SiO2_O1 | [symbol] | SiO2 | Orthorhombic | [symbol] | [symbol] | [symbol] | [symbol] | [symbol] |
| SiO2_T2 | [symbol] | SiO2 | Tetragonal | [symbol] | [symbol] | [symbol] | [symbol] | [symbol] |
| SiO2_M | [symbol] | SiO2 | [symbol] | [symbol] | [symbol] | [symbol] | [symbol] | [symbol] |
| SiO2_O2 | [symbol] | SiO2 | Orthorhombic | [symbol] | [symbol] | [symbol] | [symbol] | [symbol] |
| SiO2_H | [symbol] | SiO2 | Hexagonal | [symbol] | [symbol] | [symbol] | [symbol] | [symbol] |
| HfO2_M | [symbol] | HfO2 | [symbol] | [symbol] | [symbol] | [symbol] | [symbol] | [symbol] |
| HfO2_O | [symbol] | HfO2 | Orthorhombic | [symbol] | [symbol] | [symbol] | [symbol] | [symbol] |
| [symbol] | [symbol] | [symbol] | Orthorhombic | [symbol] | [symbol] | [symbol] | [symbol] | [symbol] |
| [symbol] | [symbol] | [symbol] | Orthorhombic | [symbol] | [symbol] | [symbol] | [symbol] | [symbol] |
| [symbol] | [symbol] | [symbol] | Orthorhombic | [symbol] | [symbol] | [symbol] | [symbol] | [symbol] |
| [symbol] | [symbol] | [symbol] | Tetragonal | [symbol] | [symbol] | [symbol] | [symbol] | [symbol] |
| [symbol] | [symbol] | [symbol] | Cubic | [symbol] | [symbol] | [symbol] | [symbol] | [symbol] |
| [symbol] | [symbol] | [symbol] | Orthorhombic | [symbol] | [symbol] | [symbol] | [symbol] | [symbol] |
| [symbol] | [symbol] | [symbol] | Orthorhombic | [symbol] | [symbol] | [symbol] | [symbol] | [symbol] |
| LAO | [symbol] | [symbol] | Cubic | [symbol] | [symbol] | [symbol] | [symbol] | [symbol] |
| [symbol] | [symbol] | [symbol] | [symbol] | [symbol] | [symbol] | [symbol] | [symbol] | [symbol] |
| YAO | [symbol] | [symbol] | Orthorhombic | [symbol] | [symbol] | [symbol] | [symbol] | [symbol] |
| [symbol] | | [symbol] | Cubic | | [symbol] | [symbol] | [symbol] | |
| [symbol] | | [symbol] | Hexagonal | [symbol] | [symbol] | [symbol] | [symbol] | [symbol] |
| [symbol] | [symbol] | [symbol] | Orthorhombic | [symbol] | [symbol] | [symbol] | [symbol] | [symbol] |
| [symbol] | [symbol] | [symbol] | Orthorhombic | [symbol] | [symbol] | [symbol] | [symbol] | [symbol] |

| index | mp-id | element | 100 | 111 |
|---|---|---|---|---|
| Cu | [symbol] | Cu | [symbol] | [symbol] |
| Ni | [symbol] | Ni | [symbol] | [symbol] |
| Si | [symbol] | Si | [symbol] | [symbol] |
| Fe | [symbol] | Fe | [symbol] | [symbol] |

Materialsprojects
Progress in Surface Science, Volume [symbol] , Issue 2 (2017) Pages 117-141 [symbol]
indicates data missing or illegible when filed

The foregoing is illustrative of exemplary embodiments and is not to be construed as limiting the disclosure. Although a few exemplary embodiments have been described, those skilled in the art will readily appreciate that many modifications are possible in the above embodiments without materially departing from the disclosure.

What is claimed is:

1. A meta-stable ferroelectric structure comprising one of the following oxides:
an isovalent combination of the formula MₓM′₁₋ₓO_{2-δ}, wherein M and M′ are independently selected from the group consisting of Zr, Hf, Pb, W, Mo, Nb, Te, and Ti, wherein 0≤x≤1 and 0≤δ≤0.5, excluding HfₓZr₁₋ₓO₂ for all x in Pca2₁ phase;
an aliovalent combination of the formula MIₓMII₁₋ₓO_{2-δ}, wherein MI and MII are independently selected from the group consisting of Bi, Y, Ta, In, Mo, Nb, Sc, Tl, Pd, Sb, W, Cr, Ge, Rh, Ti, Ag, Sn, Au, Ir, Ni, Ru, and Hg, wherein 0≤x≤1 and 0≤δ≤0.5, excluding aliovalent combinations in which MI is Ta, Nb or W where MII is Y or Sc or in which MI is Y or Sc where MII is Ta, Nb or W; or
an isovalent-aliovalent combination of the formula MₓMI_{y}MII_{1-x-y}O_{2-δ}, wherein M, MI, and MII are as set forth above and 0≤x≤1, 0≤y≤1, and 0≤δ≤0.5;
wherein the ferroelectric structure is in a Pca2₁ or Pmn2₁ space group or a subgroup thereof.

2. The meta-stable ferroelectric structure of claim 1, wherein the oxide is the isovalent combination.

3. The meta-stable ferroelectric structure of claim 1, wherein the oxide is the aliovalent combination.

4. The meta-stable ferroelectric structure of claim 1, wherein the oxide is the isovalent-aliovalent combination.

5. The meta-stable ferroelectric structure of claim 2, wherein the oxide is selected from the group consisting of PbO₂, WO₂, NbO₂, and MoO₂, and wherein the ferroelectric structure is in the Pca2₁ space group or a subgroup thereof.

6. The meta-stable ferroelectric structure of claim 2, wherein the oxide is selected from the group consisting of NbO₂, TeO₂, TiO₂, and PbO₂, and wherein the ferroelectric structure is in the Pmn2₁ space group or a subgroup thereof.

7. The meta-stable ferroelectric structure of claim 3, wherein the oxide is aliovalent combination of the formula MIₓMII₁₋ₓO₂, wherein MI and MII are independently selected from the group consisting of Bi, In, Ag, Rh, Y, Mo, Ti, W, Ni, Au, Sn, Sc, Sb, Tl, Cr, Ru, Hg, Pd, Ge, Ir, Ta, and Nb, excluding aliovalent combinations in which MI is Ta, Nb or W where MII is Y or Sc or in which MI is Y or Sc where MII is Ta, Nb or W, and wherein the ferroelectric structure is in the Pca2₁ space group of a subgroup thereof.

8. The meta-stable ferroelectric structure of claim 7, wherein MI and MII are selected from one of the following MI and MII combinations: Ta—Mo, Nb—In, Bi—Nb, Bi—In, Bi—Sc, Nb—Mo, Bi—Pd, Ta—In, Bi—Ta, Bi—Y, and Nb—Tl.

9. The meta-stable ferroelectric structure of claim 3, wherein the oxide is aliovalent combination of the formula MIₓMII₁₋ₓO₂, wherein MI and MII are independently selected from the group consisting of Bi, Nb, In, Rh, Ti, Y, Ta, W, Cr, Sc, Tl, Au, Ir, Mo, and Ge, excluding aliovalent combinations in which MI is Ta, Nb or W where MII is Y or Sc or in which MI is Y or Sc where MII is Ta, Nb or W, and wherein the ferroelectric structure is in the Pmn2₁ space group or a subgroup thereof.

10. A vertical channel transistor comprising a meta-stable ferroelectric structure of claim 1.

11. A FE-RAM comprising a meta-stable ferroelectric structure of claim 1.

12. A FTJ comprising a meta-stable ferroelectric structure of claim 1.

13. A FE-FET comprising a meta-stable ferroelectric structure of claim 1.

14. A capacitor comprising a meta-stable ferroelectric structure of claim 1.

15. A sensor comprising a meta-stable ferroelectric structure of claim 1.

16. A switch comprising a meta-stable ferroelectric structure of claim 1.

17. A meta-stable ferroelectric structure comprising one of the following oxides:
an isovalent combination of the formula MₓM′₁₋ₓO_{2-δ}, wherein M and M′ are independently selected from the group consisting of Zr, Hf, Pb, Mo, Nb, Te, and Ti, wherein 0≤x≤1 and 0≤δ≤0.5, excluding HfₓZr₁₋ₓO₂ for all x in Pca2₁ phase;
an aliovalent combination of the formula MIₓMII₁₋ₓO_{2-δ}, wherein MI and MII are independently selected from the group consisting of Bi, In, Mo, Tl, Pd, Sb, Cr, Ge, Rh, Ti, Ag, Sn, Au, Ir, Ni, Ru, and Hg, wherein 0≤x≤1 and 0≤δ≤0.5; or
an isovalent-aliovalent combination of the formula MₓMI_{y}MII_{1-x-y}O_{2-δ}, wherein M, MI, and MII are as set forth above and 0≤x≤1, 0≤y≤1, and 0≤δ≤0.5;
wherein the ferroelectric structure is in a Pca2₁ or Pmn2₁ space group or a subgroup thereof.

18. The meta-stable ferroelectric structure of claim 17, wherein the oxide is the aliovalent combination.

19. The meta-stable ferroelectric structure of claim 1, comprising one of the following oxides:
an isovalent combination of the formula MₓM′₁₋ₓO₂, wherein M and M′ are independently selected from the group consisting of Zr, Hf, Pb, W, Mo, Nb, and Te, wherein 0≤x≤1, excluding HfₓZr₁₋ₓO₂ for all x;
an aliovalent combination of the formula MIₓMII₁₋ₓO₂, wherein MI and MII are independently selected from the group consisting of Bi, Y, Ta, In, Nb, Sc, Tl, Rh, Ti, Au, and Ir, wherein 0≤x≤1, excluding aliovalent combinations in which MI is Ta or Nb where MII is Y or Sc or in which MI is Y or Sc where MII is Ta or Nb; or
an isovalent-aliovalent combination of the formula MₓMI_{y}MII_{1-x-y}O₂, wherein M, MI, and MII are as set forth above and 0≤x≤1 and 0≤y≤1;
wherein the ferroelectric structure is in a Pca2₁ or Pmn2₁ space group or a subgroup thereof.

20. The meta-stable ferroelectric structure of claim 17, comprising one of the following oxides:
an isovalent combination of the formula MₓM′₁₋ₓO₂, wherein M and M′ are independently selected from the group consisting of Zr, Hf, Pb, Mo, Nb, and Te, wherein 0≤x≤1, excluding HfₓZr₁₋ₓO₂ for all x;
an aliovalent combination of the formula MIₓMII₁₋ₓO₂, wherein MI and MII are independently selected from the group consisting of Bi, In, Tl, Rh, Ti, Au, and Ir, wherein 0≤x≤1; or
an isovalent-aliovalent combination of the formula MₓMI_{y}MII_{1-x-y}O₂, wherein M, MI, and MII are as set forth above and 0≤x≤1 and 0≤y≤1;
wherein the ferroelectric structure is in a Pca2₁ or Pmn2₁ space group or a subgroup thereof.
